(19) United States
(12) Patent Application Publication
(10) Pub. No.: US 2024/0128005 A1
(43) Pub. Date: Apr. 18, 2024

(54) Electronic device with fine pitch and thick conductors and method of making the same

(71) Applicant: Phoenix Pioneer Technology Co., Ltd., Hsinchu County (TW)

(72) Inventor: Shih-Ping Hsu, Hsinchu County (TW)

(21) Appl. No.: 18/463,542

(22) Filed: Sep. 8, 2023

(30) Foreign Application Priority Data
Oct. 14, 2022 (TW) 111139017

(51) Int. Cl. H01F 17/00; C23C 18/54; C25D 5/02; C25D 7/12; H01F 27/24; H01F 41/04

(52) U.S. Cl. CPC H01F 17/0013; C23C 18/54; C25D 5/022; C25D 7/123; H01F 27/24; H01F 41/041

(57) ABSTRACT

The invention provides an electronic device and its manufacturing method. The electronic device includes a first conductive component, which includes a first seed layer, a first conductive layer, a first conductive thickening layer, and a first insulating layer. The first seed layer has a plurality of first seed blocks. The first conductive layer has a plurality of first conductive blocks. Each of the first conductive blocks is disposed on a top surface of the first seed block, respectively. The first conductive thickening layer has a plurality of first conductive thickened blocks, which covers one side surface of each first seed block and one side surface of each first conductive block respectively. The first insulating layer covers the first seed layer, the first conductive layer, and the first conductive thickening layer.

### CROSS REFERENCE TO RELATED APPLICATIONS

This Non-provisional application claims priority under 35 U.S.C. § 119(a) on Patent Application No. 111139017 filed in Republic of China on Oct. 14, 2022, the entire contents of which are hereby incorporated by reference.

### BACKGROUND

### 1. Technical Field

The present invention relates to an electronic device and its manufacturing method, in particular to an electronic device and its manufacturing method applied to semiconductors.

### 2. Description of Related Art

In response to high-current applications, some current electronic devices require a conductive circuit structure with fine pitch and a thick conductive layer.

FIG. 1 illustrates a semi-finished electronic device 80, comprising a substrate 81, a conductive circuit layer 82, and a photoresist layer 83. The conductive circuit layer 82 is separated into conductive areas 82a-82d by the photoresist layer 83. Under the design specifications of fine pitch and a thick conductive layer, the distance between each conductive area 82a-82d is approximately 8 micrometers, and the thickness of the conductive circuit layer 82 is approximately 50 micrometers.

Under the aforementioned design requirements of fine pitch and a thick conductive layer, the photoresist layer 83 needs to utilize high-resolution negative thick-film photoresist. This is to ensure the successful formation of high-aspect-ratio openings during photolithography processes, allowing the formation of the conductive circuit layer 82 through electroplating within the openings. However, the disadvantages of a single electroplating process include: (1) limitations imposed by exposure resolution, making it extremely difficult to define fine pitch patterns using negative-tone thick-film photoresist, resulting in low yield; (2) poor adhesion of thick-film photoresist in fine pitch patterns, leading to the formation of shorts between lines during electroplating (as indicated by defect df1 in FIG. 1); (3) high-resolution thick-film photoresist requires advanced exposure equipment, which not only increases processing costs but also extends exposure time; (4) poor uniformity in electroplating the thick conductive circuit layer in a single photolithography process, leading to non-uniform thickness and a convex-shaped top surface of the conductive circuit layer, reducing its cross-sectional area and compromising its electrical performance.

Referring to FIG. 2, another conventional electronic device 90 includes a substrate 91, a seed layer 92, a first conductive layer 93a, a second conductive layer 93b, and an insulating layer 94. The first conductive layer 93a and the second conductive layer 93b are respectively formed by electroplating, so the corresponding seed layer must be reserved in different electroplating processes to conduct the current required for electroplating. Drawbacks of using multiple electroplating processes include (1) intricate processing processes; (2) in each layer-adding process of the conductive layer, it is necessary to retain the excess seed conductive area 92a from the seed layer to the substrate that facilitates current flow during electroplating. The more layer-adding processes are conducted, the more excess seed conductive area needs to be preserved; (3) an increased number of seed layers can lead to rough edges and adversely affect the electrical quality of the electronic device 90; (4) exposed seed conductive areas 92a after cutting are susceptible to oxidation and corrosion; (5) the uniformity of thick conductive layers formed through multiple electroplating processes is compromised, with thicker layers exhibiting poorer uniformity, and the top of the conductive layer presenting a convex shape that reduces its cross-sectional area, thereby diminishing its electrical properties.

Therefore, developing an electronic device with both fine pitch and thick conductors, along with a manufacturing method, remains an important challenge in the field.

### SUMMARY OF THE INVENTION

In view of the foregoing, an objective of the present invention is to provide an electronic device and its manufacturing method capable of producing microstructures with fine pitch and thick conductors, while effectively enhancing the yield rate. Additionally, another objective of the present invention is to improve the conductivity characteristics of the electronic device with fine pitch and thick conductors.

To achieve the above, an electronic device in the present invention includes at least a conductive component. It also includes a seed layer, a conductive layer, a conductive thickening layer, and an insulating layer. The seed layer has a plurality of seed blocks. The conductive layer has a plurality of conductive blocks, which are respectively disposed on a top surface of each seed block. The conductive thickening layer dads the lateral surface of each seed block, the lateral surface of each conductive block, or both the lateral and top surfaces of each conductive block. The insulating layer dads the seed layer, the conductive layer, and the conductive thickening layer.

In one embodiment, a top surface of at least parts of the first conductive blocks is exposed to the first conductive thickening layer.

In one embodiment, The first conductive thickening blocks also clad the top surface of at least parts of the first conductive block.

In one embodiment, the electronic device further includes a core layer, at least one first conductive component, and at least one second conductive component corresponding to the first conductive component. The core layer, which is disposed on the first surface, has a first surface and a second surface disposed to each other. The first conductive component is disposed on the first surface and includes a first seed layer, a first conductive layer, a first conductive thickening layer, and a first insulating layer. The second conductive component is disposed on the second surface of the core layer and includes a second seed layer, a second conductive layer, a second conductive thickening layer, and a second insulating layer.

In addition, to achieve the above, the present invention provides a method for manufacturing an electronic device to form the above-mentioned conductive component.

As previously mentioned, in the structure of the electronic device of the present invention and its manufacturing method, the part functioning as the conductive circuit includes the first conductive layer and the first conductive thickening layer. As a result, the electronic device can exhibit the characteristics of thick conductors while still having the feature of a fine pitch between conductors. When applied to, for example, coil devices, this design meets the requirements for reducing the spacing between coils, increasing the thickness, width, and cross-sectional area of coil conductors, and consequently allowing for the design of a greater number of coils within a certain range.

In the manufacturing method of the present invention, the conductive circuit with fine pitch and thick conductors is achieved by forming the conductive thickening layer based on the conductive layer by electroless plating, high-speed electroless plating, sputtering, or thin film deposition. Among them, the conductive layer is formed using electroplating. This approach helps to avoid the issues of unevenness and short circuits between circuits that can arise from attempting to create excessively thick conductive circuits in a single electroplating process. It also addresses the problems associated with using electroplated thickening layers, as known in the prior art.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

The parts in the drawings are not necessarily drawn to scale, the emphasis instead being placed upon clearly illustrating the principles of at least one embodiment. In the drawings, like reference numerals designate corresponding parts throughout the various diagrams, and all the diagrams are schematic.

FIG. 1 illustrates a cross-sectional view of a conventional electronic device.

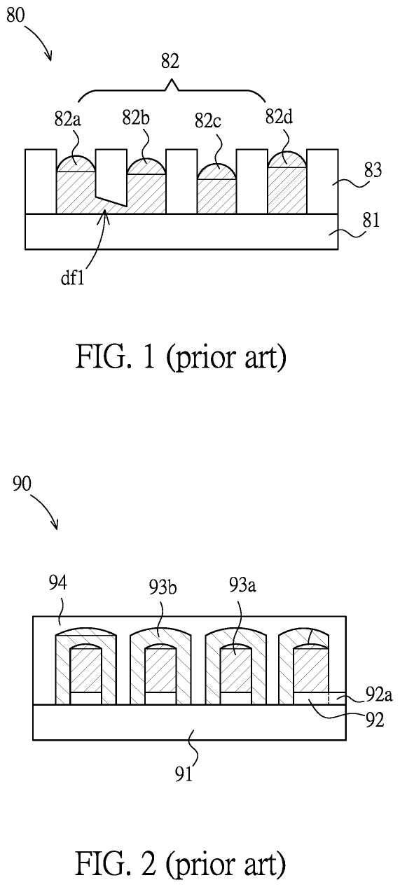

FIG. 2 illustrates a cross-sectional view of another conventional electronic device.

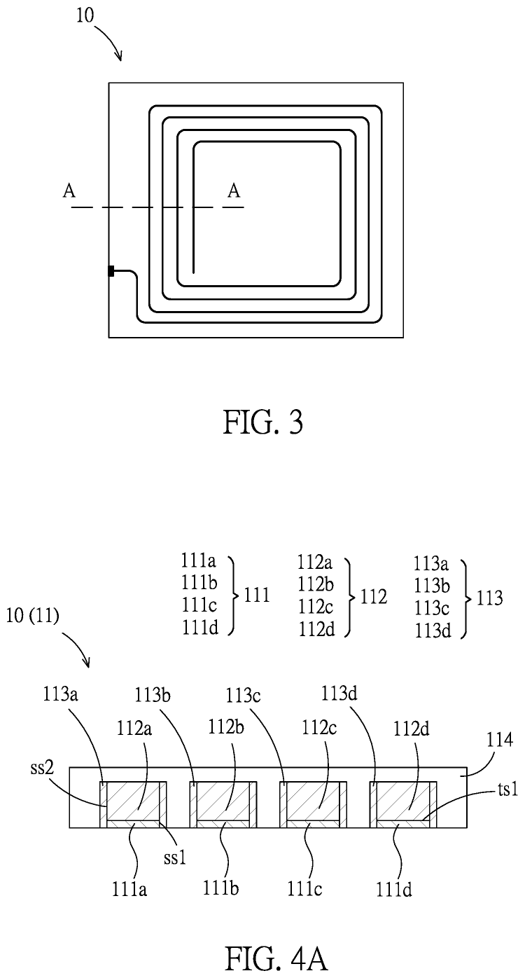

FIG. 3 is a schematic diagram showing a top view of an electronic device according to a first embodiment of the present invention.

FIG. 4A is a schematic diagram showing a cross-sectional view along line A-A in FIG. 3.

FIG. 4B is a schematic diagram showing another variation example of the electronic device according to the first embodiment.

FIG. 4C is a schematic diagram showing yet another variation example of the electronic device according to the first embodiment.

FIGS. 5A to 5J illustrate schematic diagrams of corresponding structures of the electronic device according to the manufacturing method of the first embodiment of the present invention.

FIG. 5K illustrates a schematic diagram of a corresponding structure of a variation example of the manufacturing method of the electronic device according to the first embodiment.

FIGS. 6A to 6C portray schematic diagrams of corresponding structures of the electronic device according to the manufacturing method of the second embodiment of the present invention.

FIGS. 7A to 7H depict schematic diagrams of corresponding structures of the electronic device according to the manufacturing method of the third embodiment of the present invention.

FIG. 8 illustrates a schematic diagram of an electronic device according to the fourth embodiment of the present invention.

FIG. 9 illustrates a schematic diagram of an electronic device according to the fifth embodiment of the present invention.

### DETAILED DESCRIPTION

In order to facilitate understanding of the content of the invention by those skilled in the art and to enable the implementation of the content of the invention, the following is provided in conjunction with preferred embodiments and drawings.

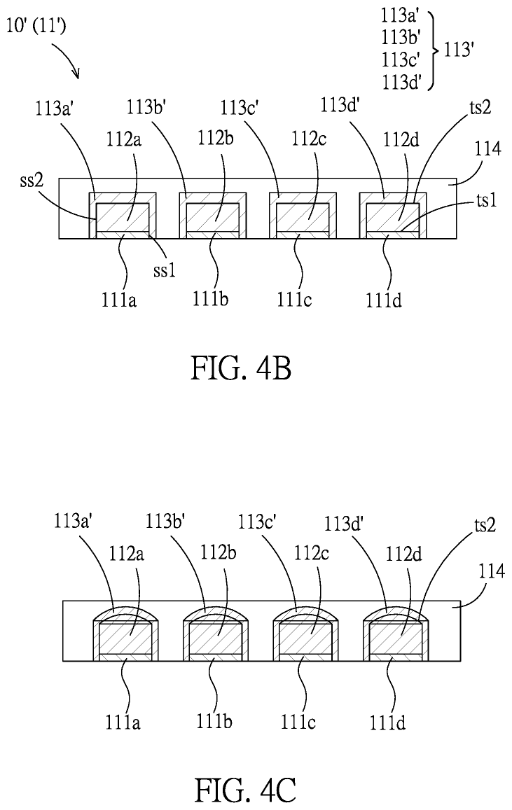

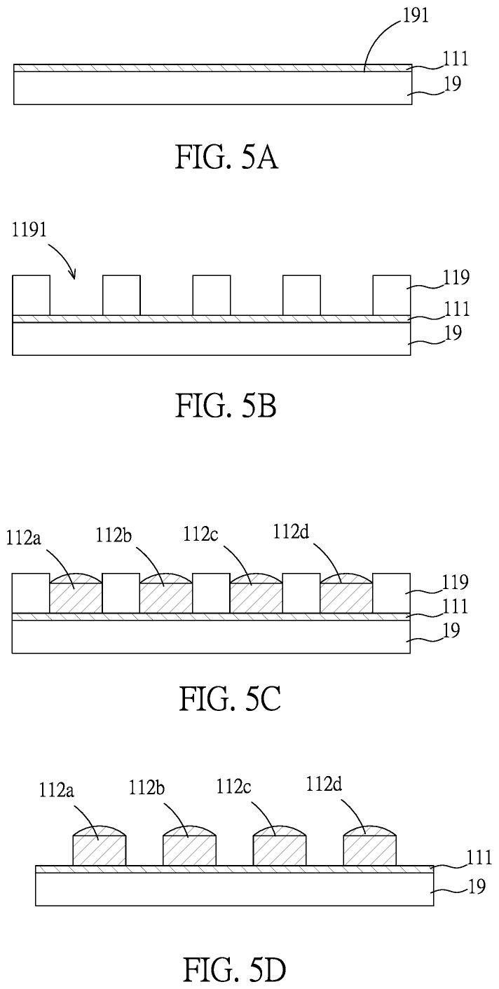

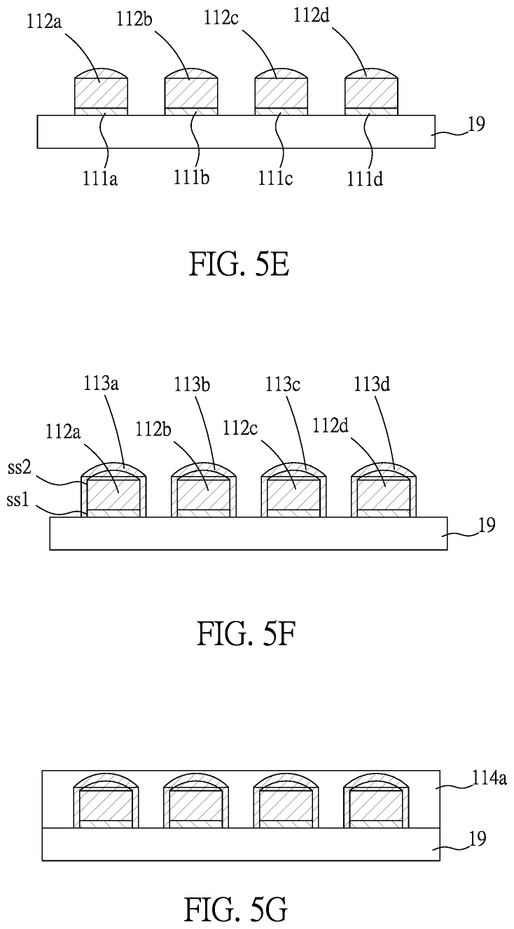

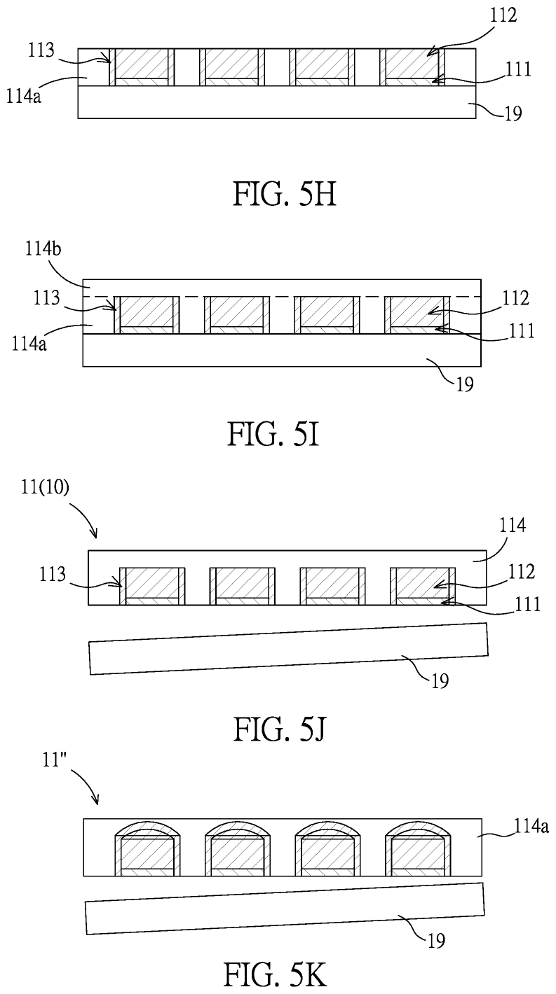

FIG. 3 depicts a top view of an electronic device 10 according to a first embodiment of the present invention. The electronic device 10 finds applications in various fields including but not limited to coil devices, magnetic components, transformers, inductors, or integrated circuit substrates. Please also refer to both FIG. 3 and FIG. 4A, where FIG. 4A represents a sectional view of the electronic device 10 along line A-A in FIG. 3.

As illustrated in FIG. 4A, the electronic device 10 includes a first conductive component 11, which has a first seed layer 111, a first conductive layer 112, a first conductive thickening layer 113, and a first insulating layer 114. Among these layers, the first seed layer 111, the first conductive layer 112, and the first conductive thickening layer 113 each have multiple regions (or blocks), which will be elaborated on individually.

The first seed layer 111 has a plurality of first seed blocks 111a-111d, arranged in the same plane and adjacent positions. These blocks can be connected or isolated (separated) from each other based on requirements. The material of the first seed layer 111 includes, but is not limited to, copper foil, comprising copper (Cu), titanium (Ti), nickel (Ni), silver (Ag), palladium (Pd), tin (Sn), and their combinations, or alloys thereof.

The first conductive layer 112 is positioned on the first seed layer 111 and has a plurality of first conductive blocks 112a-112d, which are flat-surface. These blocks are disposed on the respective top surface ts1 of each corresponding first seed block 111a-111d. The material of the first conductive layer 112 is chosen depending on the material of the first seed layer 111, and may include, but is not limited to, copper, nickel, iron (Fe), cobalt (Co), manganese (Mn), zinc (Zn), and their combinations, or alloys thereof.

The first conductive thickening layer 113 has a plurality of first conductive thickening blocks 113a-113d, each cladding the lateral surface ss1 of each first seed block 111a-111d and the lateral surface ss2 of each corresponding first conductive block 112a-112d. The material of the first conductive thickening layer 113 includes, but is not limited to, copper, nickel, iron (Fe), cobalt (Co), manganese (Mn), zinc (Zn), and their combinations, or alloys thereof. The thickness of each first conductive thickening block 113a-113d is approximately within the range of 2 um to 30 um. It is to be noted that the first conductive thickening layer 113 can have the same or different material composition as the first conductive layer 112.

The first insulating layer 114 clads the first seed layer 111, the first conductive layer 112, and the first conductive thickening layer 113. In this context, the term “dads” is not limited to physical contact; for instance, the first seed layer 111 may not have direct physical contact with the first insulating layer 114, and its positioning remains within the confines of the first insulating layer 114, which is still considered cladding. Additionally, the material of the first insulating layer 114 can be either photosensitive or non-photosensitive liquid or film dielectric materials, which includes, but is not limited to, EMC, BT, PI, ABF, PI/Epoxy, FR4, FR5, or solder mask ink.

As described above, in the structure of the aforementioned electronic device 10, the conductive circuit part includes the first conductive layer and the first conductive thickening layer. This arrangement endows the electronic device 10 with the feature of thick conductors while maintaining the fine pitch feature between conductors. When applied, for example, in coil devices, this design accommodates reducing the spacing between coils, increasing the thickness, width, and cross-sectional area of coil conductors. Consequently, a greater number of coils can be designed within a specified range. It is to be noted that the term “fine pitch” refers to the spacing between conductive thickening blocks being equal to or less than 8 micrometers (um), while “thick conductors” indicate a combined thickness of the conductive block and the conductive thickening block exceeding 50 micrometers (um).

Additionally, FIG. 4B illustrates an electronic device 10′, which is a variation of the electronic device 10. In this variant, the first conductive thickening layer 113′ includes a plurality of first conductive thickening blocks 113a′-113d′. These blocks respectively clad the lateral surface ss1 of each first seed block 111a-111d, the lateral surface ss2 of each first conductive block 112a-112d, and the top surface ts2 (112a-112d) of each first conductive block 112a-112d. Notably, the top surface ts2 of each first conductive block 112a-112d can be either planar (as shown in FIG. 4B) or non-planar (as shown in FIG. 4C). In other words, the difference from FIG. 4A lies in the fact that each of the first conductive thickening blocks 113a′-113d′ additionally covers the top surface ts2 of each corresponding first conductive block 112a-112d.

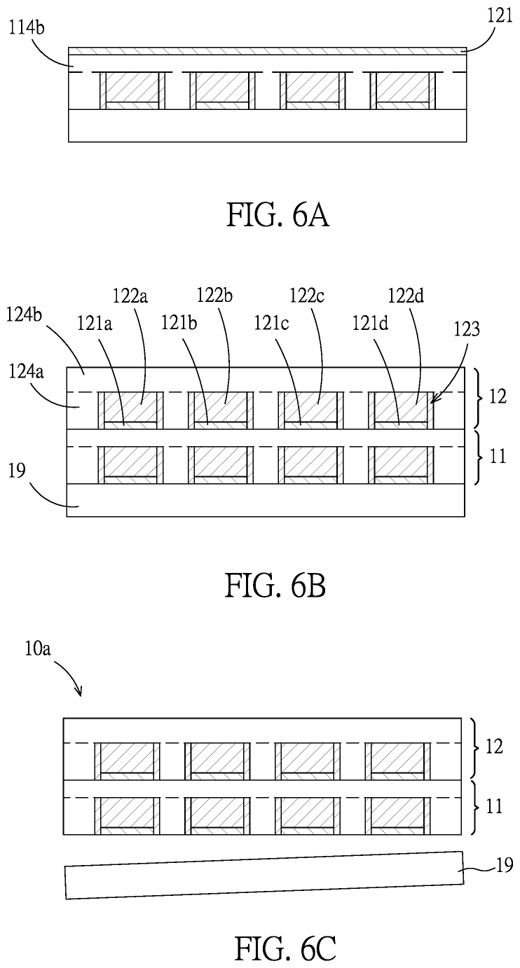

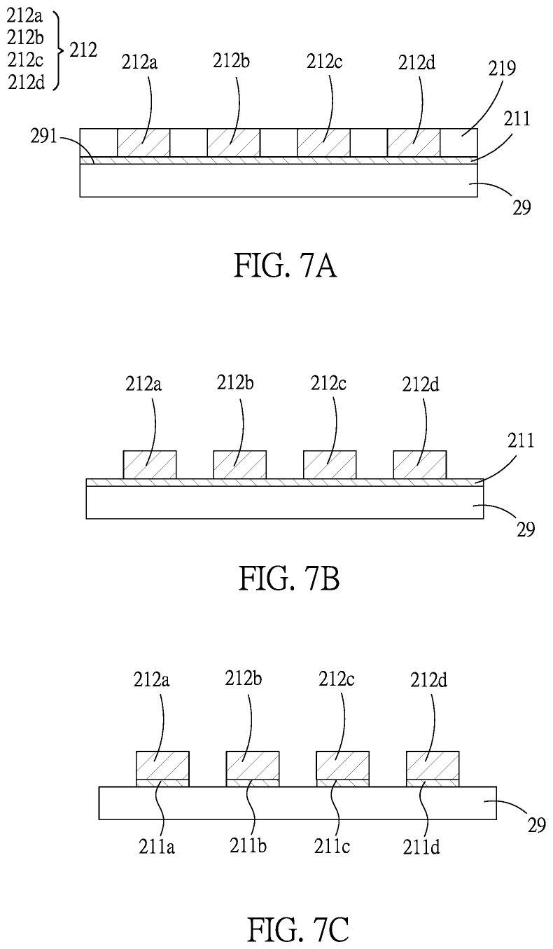

Please refer to FIGS. 5A to 5J for an explanation of the manufacturing method of the electronic device 10 according to the first embodiment of the present invention.

As shown in FIG. 5A, Step S101 involves forming a first seed layer 111 on a surface 191 of a carrier board 19. The first seed layer 111 is formed using methods such as sputtering or electroless plating on the surface 191 of the carrier board 19. The material of the first seed layer 111 may include copper, titanium, nickel, silver, palladium, tin, their combinations, or alloys thereof. In this step, the first seed layer 111 is formed over the entire surface 191. It is to be noted that the carrier board 19 possesses a removable structure, which could be the substrate with the core layer, a metal plate, a combination of metal plates and insulating layers, or other suitable carrier board.

As shown in FIG. 5B, Step S102 involves forming a first photoresist layer 119 on the first seed layer 111. The first photoresist layer 119 has a plurality of openings 1191 to expose parts of the first seed layer 111. The first photoresist layer 119 can be initially formed over the entire first seed layer 111 and then patterned by processes like exposure and development to form openings 1191. It should be noted that the shape of the openings 1191, which expose portions of the first seed layer 111, is not limited to hole-like, groove-like, or any other specific types.

As shown in FIG. 5C, Step S103 involves electroplating a first conductive layer 112 onto the exposed regions of the first seed layer 111 through the openings 1191 in the first photoresist layer 119. The first conductive layer 112 is divided into the first conductive blocks 112a-112d by the first photoresist layer 119. The top surfaces of the first conductive blocks 112a-112d are formed in a raised shape.

As shown in FIG. 5D, Step S104 involves removing the first photoresist layer 119. Then, as illustrated in FIG. 5E, Step S105 involves removing the parts of the first seed layer 111 that are not covered by the first conductive layer 112, resulting in the separation of the first seed layer 111 into a plurality of first seed blocks 111a-111d.

As shown in FIG. 5F, Step S106 involves forming a first conductive thickening layer 113 around the outer edges of the first conductive blocks 112a-112d. The first conductive thickening layer 113 is divided into a plurality of first conductive thickening blocks 113a-113d corresponding to the first conductive blocks 112a-112d. The first conductive thickening layer 113 can be formed using methods such as electroless plating to thicken copper, sputtering, or other thin-film deposition techniques. Depending on whether chemical reactions are involved in the deposition process, deposition techniques can be classified as Physical Vapor Deposition (PVD) or Chemical Vapor Deposition (CVD). In this embodiment, the preferred method for forming the first conductive thickening layer 113 is high-speed electroless plating to thicken copper.

As shown in FIG. 5G, Step S107 involves forming the first insulating layer 114a to clad the first seed layer 111, the first conductive layer 112, and the first conductive thickening layer 113. The first insulating layer 114a can be formed using methods such as vacuum lamination, coating, printing, or hot pressing.

As shown in FIG. 5H, Step S108 involves performing a leveling process on the side of the first insulating layer 114a, the first conductive layer 112, and the first conductive thickening layer 113 opposite to the carrier board 19. The leveling process can involve techniques like polishing, grinding, or buffing, which make the surface of the first insulating layer 114a, the first conductive layer 112, and the first conductive thickening layer 113 on the side away from the carrier board 19 form a coplanar surface.

As shown in FIG. 5I, Step S109 involves forming the first insulating layer 114b on the coplanar surface forming by the first insulating layer 114a, the first conductive layer 112, and the first conductive thickening layer 113. The combination of the first insulating layer 114a and the first insulating layer 114b constitutes the complete first insulating layer 114. Due to the first insulating layer 114b is situated on the outer layer, its material can include not only the previously mentioned EMC, BT, PI, ABF, PI/Epoxy, FR4, FR5, or solder mask ink, but also film-like dielectric materials.

Next, as shown in FIG. 5J, Step S110 involves removing the carrier board 19 to form the first conductive component 11. In certain application domains, the first conductive component 11 can be utilized as the electronic device 10.

It is worth noting that after forming the first insulating layer 114a to clad the first seed layer 111, the first conductive layer 112, and the first conductive thickening layer 113, as shown in FIG. 5G, the process can proceed directly to the steps illustrated in FIG. 5K, namely removing the carrier board 19 to form the first conductive component 11″.

Please refer to the relevant diagrams to explain the electronic device and its manufacturing method according to the second embodiment of the present invention. In the second embodiment, the manufacturing method of the electronic device continues after Step S109 of the first embodiment. In other words, the manufacturing method of the second embodiment is the same as that of the first embodiment, including steps S101 to S109. Here, the redundant description of those steps will be omitted.

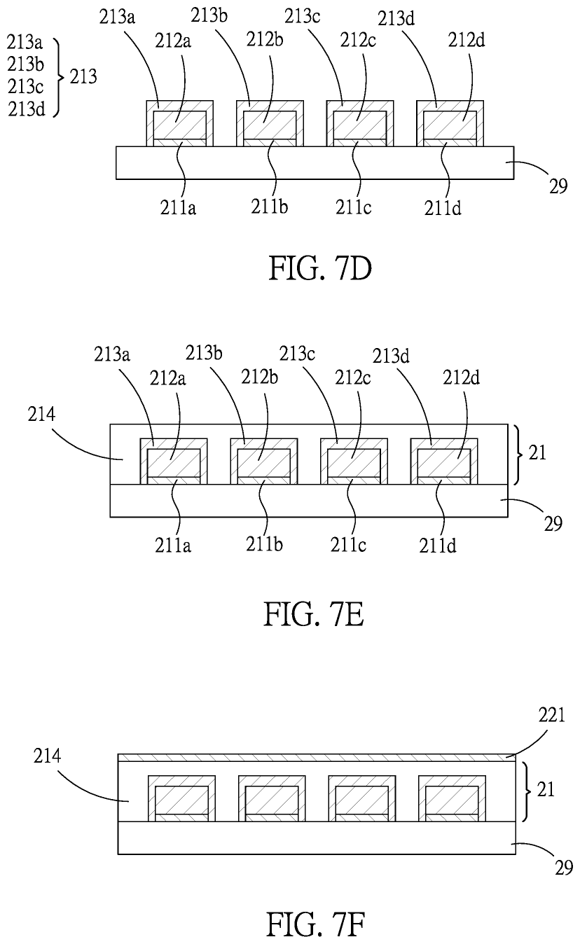

As shown in FIG. 6A, following step S109, a second seed layer 121 is formed on the first insulating layer 114b. Then, as depicted in FIG. 6B, steps similar to those of the first embodiment from step S102 to step S109 are repeated. In more detail, a second photoresist layer with multiple openings is formed on the second seed layer 121. Then, a second conductive layer 122 is electroplated onto the second seed layer 121 within the openings of the second photoresist layer. The second conductive layer 122 is divided into the second conductive blocks 122a-122d. Next, the second photoresist layer is removed, followed by removing the parts of the second seed layer 121 not covered by the second conductive layer 122, resulting in the distinction of multiple second seed blocks 121a-121d within the second seed layer 121. Following this, a second conductive thickening layer 123 is formed along the outer edges of the second conductive blocks 122a-122d. Subsequently, a second insulating layer 124a is applied to clad the second seed layer 121, the second conductive layer 122, and the second conductive thickening layer 123. Then, a leveling process is performed on the side of the second insulating layer 124a, the second conductive layer 122, and the second conductive thickening layer 123 that is away from the carrier board 19 and the first conductive component 11. Then, a second insulating layer 124b is formed on a coplanar surface formed by the second insulating layer 124a, the second conductive layer 122, and the second conductive thickening layer 123. At this point, the manufacturing method of forming the second conductive component 12 on the first conductive component 11 is illustrated. Of course, in other embodiments, the process steps for the conductive component can be repeated to form a multilayer conductive component structure.

Finally, as shown in FIG. 6C, the carrier board 19 is removed to form an electronic device 10a including both the first conductive component 11 and the second conductive component 12. It is worth mentioning that in this embodiment, when there is a need for electrical connection between the second conductive component 12 and the first conductive component 11, vias can be formed in the first insulating layer 114b before forming the second seed layer 121. Conductive interconnect elements can be formed within these vias to establish electrical connections. This approach allows the establishment of an electrical connection between the second conductive component 12 and the first conductive component 11 after forming the second seed layer 121. Vias can be formed using processes such as photolithography or laser drilling, while conductive interconnect elements can take the form of conductive pillars or similar means.

Subsequently, referring to the relevant diagrams, a third embodiment of the present invention involves explaining the electronic device and its manufacturing method. The manufacturing method of the third embodiment includes steps S201 through S216. Among these, steps S201 to S203 are similar to steps S101 to S103 of the first embodiment, so steps S201 to S203 are only briefly described below.

Step S201 is to form a first seed layer 211 on a surface 291 of a carrier board 29. The first seed layer 211 is formed on the surface 291 of the carrier board 29 through methods like sputtering or electroless plating. Step S202 is to form a first photoresist layer 219 with multiple openings on the first seed layer 211. Step S203 is to electroplate a first conductive layer 212 onto the first seed layer 211 within the openings of the first photoresist layer 219. By utilizing the first photoresist layer 219, the first conductive layer 212 is divided into a plurality of first conductive blocks 212a-212d.

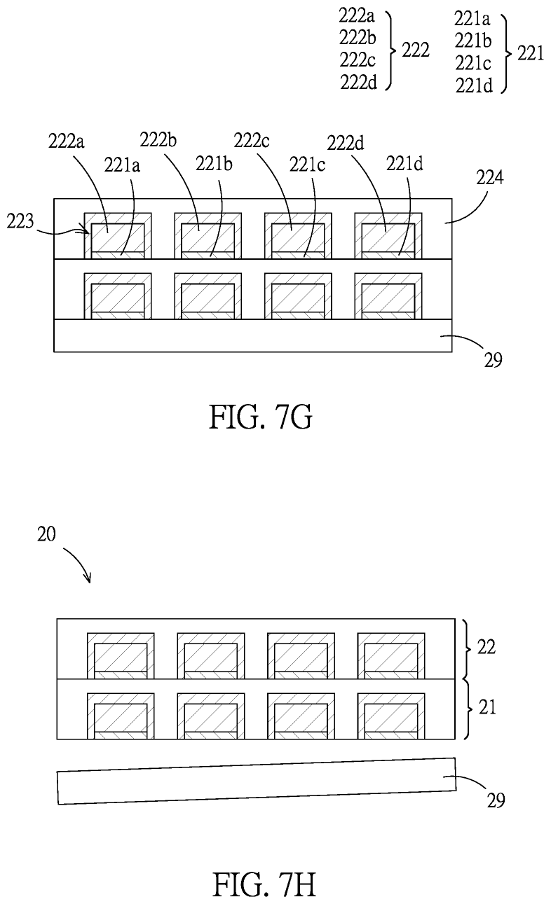

Next, as shown in FIG. 7A, step S204 involves performing a leveling process on the side of the first photoresist layer 219 and the first conductive layer 212 that is away from the carrier board 29. The leveling process, which can include methods such as polishing, grinding, or buffing, serves to achieve a coplanar surface for both the first photoresist layer 219 and the first conductive layer 212, relative to the carrier board 29.

As shown in FIG. 7B, step S205 is to remove the first photoresist layer 219. Furthermore, as shown in FIG. 7C, step S206 is to remove the portions of the first seed layer 211 that remain uncovered by the first conductive layer 212. This process differentiates the first seed layer 211 into a plurality of first seed blocks 211a-211d.

Next, as shown in FIG. 7D, Step S207 involves forming a first conductive thickening layer 213 along the periphery of the first conductive blocks 212a-212d. Depending on the arrangement of the first conductive blocks 212a-212d, the first conductive thickening layer 213 is divided into a plurality of first conductive thickening blocks 213a-213d. The first conductive thickening layer 213 can be formed through methods such as electroless plating, sputtering, or other thin-film deposition techniques. Depending on whether chemical reactions are involved in the deposition process, thin-film deposition can be classified as physical vapor deposition (PVD) or chemical vapor deposition (CVD). In this embodiment, a preferable approach for forming the first conductive thickening layer 213 is high-speed electroless plating to thicken copper.

As shown in FIG. 7E, step S208 is to form a first insulating layer 214 to cover the first seed layer 211, the first conductive layer 212 and the first conductive thickening layer 213. The first insulating layer 214 can be formed by vacuum lamination, coating, printing or hot pressing. Here, the first insulating layer 214, the first seed layer 211, the first conductive layer 212 and the first conductive thickening layer 213 constitute a first conductive component 21.

As shown in FIG. 7F, step S209 comprehensively forms a second seed layer 221 on the first insulating layer 214. Next, as shown in FIG. 7G, the above steps S202 to S208 are similarly repeated. Specifically, the next step S210 is to form a second photoresist layer with a plurality of openings on the second seed layer 221. Step S211 is to form a second conductive layer 222 on the second seed layer 221 by electroplating in the opening of the second photoresist layer. The second conductive layer 222 is divided into a plurality of second conductive blocks 222a-222d. Step S212 involves performing a leveling process on the side of the second photoresist layer and the second conductive layer 222 that is away from the carrier board 29. After the leveling process, the surfaces of the second photoresist layer and the second conductive layer 222 away from the carrier plate 29 and the first conductive component 21 form a coplanar surface. Step S213 is to remove the second photoresist layer, and then remove the second seed layer 221 that is not covered by the second conductive layer 222 so that the second seed layer 221 is divided into a plurality of second seed blocks 221a-221d. Then step S214 is to form a second conductive thickening layer 223 on the outer edge of the second conductive blocks 222a-222d. Then step S215 is to form the second insulating layer 224 to clad the second seed layer 221, the second conductive layer 222, and the second conductive thickening layer 223. Here, the second insulating layer 224, the second seed layer 221, the second conductive layer 222, and the second conductive thickening layer 223 constitute a second conductive component 22.

Finally, as shown in FIG. 7H, step S216 involves removing the carrier board 29 to form an electronic device 20 including the first conductive component 21 and the second conductive component 22. Similarly to the previous embodiments, the electrical connection between the first conductive component 21 and the second conductive component 22 can also be achieved through conductive elements, and further elaboration on this aspect is not necessary here.

It is worth mentioning that in the manufacturing method of the third embodiment, it is also possible to remove the carrier board 29 after step S208 to form an electronic device 20 consisting only of the first conductive component 21.

The difference between the electronic device 20 produced by the manufacturing method of the third embodiment and the electronic device 10 or 10a produced by the first or second embodiments lies in whether the conductive thickening blocks are cladding the top surfaces of the corresponding conductive blocks. However, both structures can achieve the features of fine pitch and thick conductors.

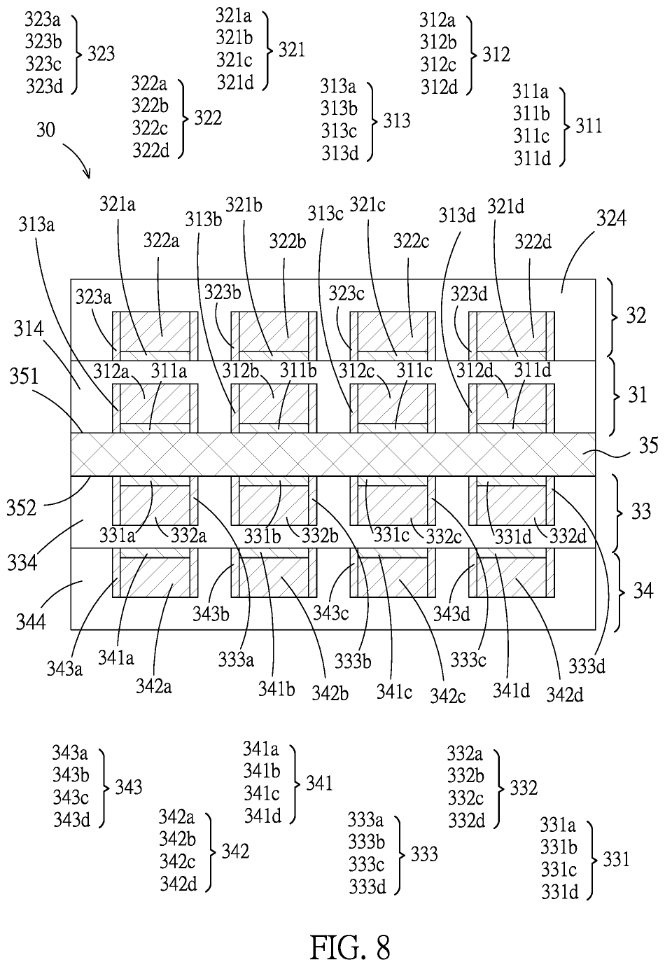

Please refer to FIG. 8 to explain the electronic device 30 of the fourth embodiment of the present invention. As shown in FIG. 8, the electronic device 30 includes a first conductive component 31, a second conductive component 32, a third conductive component 33, a fourth conductive component 34, and a core layer 35.

The core layer 35 has a first surface 351 and a second surface 352 that are relative to each other. The core layer 35 can be a carrier board, circuit board, etc. Its material may include but is not limited to EMC, BT, PI, ABF, PI/Epoxy, FR4, FR5, and these materials can be with or without glass fiber.

The first conductive component 31 is disposed on the first surface 351 of the core layer 35, while the second conductive component 32 is disposed on the first conductive component 31. Furthermore, the second conductive component 32 is disposed on one side away from the core layer 35 of the first conductive component 31. The third conductive component 33 is disposed on the second surface 352 of the core layer 35, and the fourth conductive component 34 is disposed on the third conductive component 33. To elaborate further, the fourth conductive component 34 is disposed on one side away from the core layer 35 of the third conductive component 33.

The first conductive component 31 includes a first seed layer 311, a first conductive layer 312, a first conductive thickening layer 313, and a first insulating layer 314. The first seed layer 311 is disposed on the first surface 351 of the core layer 35 and has a plurality of first seed blocks 311a-311d that are placed in the same plane and adjacent to each other. The first conductive layer 312 is disposed on the first seed layer 311 and has a plurality of first conductive blocks 312a-312d, each located on a corresponding first seed block 311a-311d. The first conductive thickening layer 313 includes a plurality of first conductive thickening blocks 313a-313d, which individually clad the lateral surfaces of each first seed block 311a-311d and the lateral surfaces of each first conductive block 312a-312d. The first insulating layer 314 dads a portion of the first surface 351 of the core layer 35, the first seed layer 311, the first conductive layer 312, and the first conductive thickening layer 313.

The second conductive component 32 includes a second seed layer 321, a second conductive layer 322, a second conductive thickening layer 323, and a second insulating layer 324. The second seed layer 321 is disposed on the first insulating layer 314 and has a plurality of second seed blocks 321a-321d, which are placed in the same plane and adjacent to each other. The second conductive layer 322 is disposed on the second seed layer 321 and has a plurality of second conductive blocks 322a-322d, each disposed on a corresponding second seed block 321a-321d. The second conductive thickening layer 323 has a plurality of second conductive thickening blocks 323a-323d, individually cladding the lateral surfaces of each second seed block 321a-321d and the lateral surfaces of each second conductive block 322a-322d. The second insulating layer 324 dads the second seed layer 321, the second conductive layer 322, and the second conductive thickening layer 323.

The third conductive component 33 includes a third seed layer 331, a third conductive layer 332, a third conductive thickening layer 333, and a third insulating layer 334. The third seed layer 331 is disposed on the second surface 352 of the core layer 35 and has a plurality of third seed blocks 331a-331d, which are placed in the same plane and adjacent to each other. The third conductive layer 332 is disposed on the third seed layer 331 and has a plurality of third conductive blocks 332a-332d, each positioned on a corresponding third seed block 331a-331d. The third conductive thickening layer 333 has a plurality of third conductive thickening blocks 333a-333d, individually cladding the lateral surfaces of each third seed block 331a-331d and the lateral surfaces of each third conductive block 332a-332d. The third insulating layer 334 dads part of the second surface 352 of the core layer 35, the third seed layer 331, the third conductive layer 332, and the third conductive thickening layer 333.

The fourth conductive component 34 includes a fourth seed layer 341, a fourth conductive layer 342, a fourth conductive thickening layer 343, and a fourth insulating layer 344. The fourth seed layer 341 is disposed on the third insulating layer 334 and has a plurality of fourth seed blocks 341a-341d, which are placed in the same plane and adjacent to each other. The fourth conductive layer 342 is disposed on the fourth seed layer 341 and has a plurality of fourth conductive blocks 342a-342d, each positioned on a corresponding fourth seed block 341a-341d. The fourth conductive thickening layer 343 has a plurality of fourth conductive thickening blocks 343a-343d, individually cladding the lateral surfaces of each fourth seed block 341a-341d and the lateral surfaces of each fourth conductive block 342a-342d. The fourth insulating layer 344 dads the fourth seed layer 341, the fourth conductive layer 342, and the fourth conductive thickening layer 343.

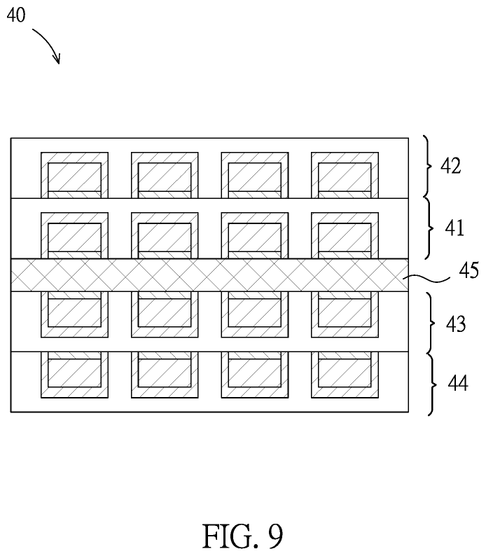

Subsequently, please refer to FIG. 9 to illustrate the fifth embodiment of an electronic device 40 of the present invention. As shown in FIG. 9, the electronic device 40 includes a first conductive component 41, a second conductive component 42, a third conductive component 43, a fourth conductive component 44, and a core layer 45. In this embodiment, the first conductive component 41, the second conductive component 42, the third conductive component 43, the fourth conductive component 44, and the core layer 45 are essentially similar to the first conductive component 31, the second conductive component 32, the third conductive component 33, the fourth conductive component 34, and the core layer 35 of the fourth embodiment. The distinction lies in that within each conductive component, the conductive thickening layer not only clads the lateral surfaces of each seed block and each conductive block but also clads the top surface of each conductive block.

It is worth mentioning that the manufacturing methods of the electronic device in the fourth and fifth embodiments mentioned above are similar to the previously described methods. The main difference lies in replacing the carrier board with the core layer and executing a double-sided additive process to complete the structure. Furthermore, although the electronic device in the fourth and fifth embodiments is presented as an example of a double-sided additive structure, it can also have a single-sided configuration, where the conductive components are present only on one side of the core layer. While the above embodiments illustrated single or double-layer conductive components, the stacking of additional layers is also possible and not limited herein.

In conclusion, the electronic device of the present invention with fine pitch and thick conductors, along with its manufacturing methods, provide the following advantages:

1. In the manufacturing process, the conductive layer is formed through a single electroplating process, while the conductive thickening layer is formed at the periphery of the conductive layer using a single electroless electroplating process. This approach facilitates a more controllable and feasible formation of conductor circuits with fine pitch and thick conductors. This approach also helps to prevent potential short-circuit issues that might arise from forming thick conductors in a single step.

2. The need for forming conductor circuits with high aspect ratios in a single process is eliminated, thus reducing the requirement for expensive high-resolution photoresist in the manufacturing process, subsequently lowering production costs.

3. Through a single electroplating process, a single electroless electroplating process, and subsequent leveling processes, the uniformity in terms of thickness, width, spacing, and cross-sectional area of the conductor circuits can be achieved. This uniformity enhances the conductivity and reliability of the electronic device.

Even though numerous characteristics and advantages of certain inventive embodiments have been set out in the foregoing description, together with details of the structures and functions of the embodiments, the disclosure is illustrative only. Changes may be made in detail, especially in matters of arrangement of parts, within the principles of the present disclosure to the full extent indicated by the broad general meaning of the terms in which the appended claims are expressed.

What is claimed is:

1. An electronic device, comprising:
a conductive component, comprising:
a seed layer, which has a plurality of seed blocks;
a conductive layer having a plurality of conductive blocks respectively disposed on a top surface of each seed block, wherein the top surfaces of the conductive blocks are either in a flat coplanar shape;
a conductive thickening layer disposed at a lateral surface of each seed block and a lateral surface of each conductive block, wherein the top surfaces of the conductive blocks are either not disposed with the conductive thickening layer or are all disposed with the conductive thickening layer; and
an insulating layer, which dads the seed layer, the conductive layer, and the conductive thickening layer.

2. The electronic device of claim 1 further comprises a plurality of additional conductive components, wherein the additional conductive components are integrated in a stacked arrangement.

3. The electronic device of claim 2 further comprises a core layer structure with a conductive circuit, wherein both a top and a bottom surfaces of the core layer are integrated with a plurality of stacked conductive components, wherein the conductive components are correspondingly and identically.

4. The electronic device of claim 1 further comprises a core layer structure with a conductive circuit, wherein both a top and a bottom surfaces of the core layer are integrated with the single conductive component, wherein the conductive components are correspondingly and identically.

5. The electronic device of claim 1, wherein the material of the seed layer comprises one of copper, nickel, silver, palladium, tin, and titanium, or a combination thereof, or an alloy of a combination thereof.

6. The electronic device of claim 1, wherein the material of the conductive layer and/or the conductive thickening layer comprises one of copper, nickel, iron, cobalt, zinc, manganese, or a combination thereof, or an alloy of a combination thereof, wherein the conductive layer and the conductive thickening layer are made of the same or different materials.

7. A manufacturing method of an electronic device, comprising:
proving a carrier board;
forming a seed layer on a surface of the carrier board;
forming a photoresist layer with a plurality of openings on the seed layer by patterning lithography process and electroplating to form a plurality of conductive blocks within the openings, wherein the conductive blocks are formed as a patterned conductive layer;
removing the photoresist layer to expose part of the surface of the seed layer and to expose a lateral surface and a top surface of the conductive blocks, wherein a plurality of seed blocks are formed at the seed layer clad by the conductive blocks;
removing the seed layer, which is not clad by the conductive blocks;
forming a conductive thickening layer to clad the lateral surface of the seed blocks and to clad the lateral surface and the top surface of the conductive blocks;
forming an insulating layer with an insulating material to clad the conductive thickening layer and the surface of the carrier board; and
removing the carrier board to expose the seed blocks and a bottom surface of the insulating layer, wherein the seed layer, the conductive layer, the conductive thickening layer, and the insulating layer form a conductive component.

8. The manufacturing method of the electronic device of claim 7, wherein before performing the step of removing the carrier board, further comprising:
performing a leveling process to remove a part of the insulating layer, a part of the conductive thickening layer, and a part of the conductive blocks so that the top surfaces of the conductive blocks form a flat coplanar surface; and
forming another insulating layer on the insulating layer with an insulating material to clad the conductive thickening layer, the top surfaces of the conductive blocks, and the surface of the insulating layer, which are exposed.

9. The manufacturing method of the electronic device of claim 7, wherein before performing the step of removing the photoresist layer, further comprising:
performing a leveling process to remove a part of the photoresist layer and a part of the conductive blocks so that the top surfaces of the conductive blocks form a flat coplanar surface; and
no other leveling process is performed in other subsequent process.

10. The manufacturing method of the electronic device of claim 7, wherein before performing the step of removing the carrier board, further comprises repeating the process of forming the conductive component several times to form a plurality of stacked conductive components.

11. The manufacturing method of the electronic device of claim 8, wherein before performing the step of removing the carrier board, further comprises repeating the process of forming the conductive component several times to form a plurality of stacked conductive components.

12. The manufacturing method of the electronic device of claim 9, wherein before performing the step of removing the carrier board, further comprises repeating the process of forming the conductive component several times to form a plurality of stacked conductive components.

13. The manufacturing method of the electronic device of claim 7, further comprises synchronously executing all the processes described in claim 7 on another surface of the carrier board to simultaneously form another conductive component corresponding to the conductive component on the bottom surface of the carrier board, wherein the carrier board is a core layer structure with a conductive circuit, and the carrier board is not removed in subsequent processes.

14. The manufacturing method of the electronic device of claim 13, further comprises repeating the process of forming the conductive component several times to form a plurality of stacked conductive components on a top surface and a bottom surface of the core layer structure, respectively.

15. The manufacturing method of the electronic device of claim 8, further comprises synchronously executing all the processes described in claim 8 on another surface of the carrier board to simultaneously form another conductive component corresponding to the conductive component on the bottom surface of the carrier board, wherein the carrier board is a core layer structure with a conductive circuit, and the carrier board is not removed in subsequent processes.

16. The manufacturing method of the electronic device of claim 15, further comprises repeating the process of forming the conductive component several times to form a plurality of stacked conductive components on a top surface and a bottom surface of the core layer structure, respectively.

17. The manufacturing method of the electronic device of claim 9, further comprises synchronously executing all the processes described in claim 9 on another surface of the carrier board to simultaneously form another conductive component corresponding to the conductive component on the bottom surface of the carrier board, wherein the carrier board is a core layer structure with a conductive circuit, and the carrier board is not removed in subsequent processes.

18. The manufacturing method of the electronic device of claim 17, further comprises repeating the process of forming the conductive component several times to form a plurality of stacked conductive components on a top surface and a bottom surface of the core layer structure, respectively.
